(19) United States
(12) Patent Application Publication
(10) Pub. No.: US 2010/0213792 A1
(43) Pub. Date: Aug. 26, 2010

(54) MULTILAYERED PIEZOELECTRIC ELEMENT AND ULTRASONIC MOTOR

(75) Inventors: Nagahide SAKAI, Higashimurayama-shi (JP); Yasuaki KASAI, Saitama-shi (JP); Junji OKADA, Hachioji-shi (JP); Katsuji HORIUCHI, Hachioji-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/772,324

(22) Filed: May 3, 2010

Related U.S. Application Data
(63) Continuation of application No. PCT/JP2008/067114, filed on Sep. 22, 2008.

(30) Foreign Application Priority Data
Nov. 5, 2007 (JP) 2007-287895

(51) Int. Cl. H02N 2/04; H01L 41/083

(52) U.S. Cl. 310/323.16; 310/366

(57) ABSTRACT

A multilayered piezoelectric element in which first internal electrodes include first exposed portions formed at the end portion of a first piezoelectric material. And the second internal electrodes include second exposed portions formed at the end portion of a second piezoelectric material.

### CROSS-REFERENCE TO RELATED APPLICATIONS

This is a Continuation Application of PCT Application No. PCT/JP2008/067114, filed Sep. 22, 2008, which was published under PCT Article 21(2) in Japanese.

This application is based upon and claims the benefit of priority from prior Japanese Patent Application No. 2007-287895, filed Nov. 5, 2007, the entire contents of which are incorporated herein by reference.

### BACKGROUND OF THE INVENTION

1. Field of the Invention

The present invention relates to a multilayered piezoelectric element and ultrasonic motor.

2. Description of the Related Art

Recently, an ultrasonic motor using the vibration of a vibrator such as a multilayered piezoelectric element is attracting attention as a new motor that replaces an electromagnetic motor. Compared to the conventional electromagnetic motor, this ultrasonic motor has the advantages that a high torque is obtained at low velocity without any gears, the holding force is high, the stroke is long, the resolution is high, the quietness is high, and the motor is not affected by magnetic noise because it generates no magnetic noise.

The ultrasonic motor as described above mainly uses a multilayered piezoelectric element as a vibrator. When compared to a single-layered, plate-like piezoelectric material having the same thickness, for example, the multilayered piezoelectric element can obtain a large deformation strain and high generating power at a low application voltage. Accordingly, the multilayered piezoelectric element is recently particularly used as a vibrator forming a vibrating driving device such as an ultrasonic motor.

As the degree of downsizing and accuracy of the multilayered piezoelectric element have increased in recent years, demands have arisen for increasing the stacking accuracy when stacking layers of the multilayered piezoelectric element. Note that if no high stacking accuracy is maintained, a shift occurs when stacking layers. If this shift increases, it is of course impossible to satisfactorily achieve the original function of the multilayered piezoelectric element.

For example, a shift of an electrode layer reduces the area of a counterelectrode as a piezoelectric element, thereby degrading the piezoelectric characteristics. If a shift of a through hole electrode is extreme, electrical connection becomes impossible, so it is no longer possible to connect electrode layers. Even when the electrode layers are connected, the connection is imperfect, and the electrical resistance of the conductor electrode increases. This may generate a power loss. Also, if the stacking accuracy is low, the multilayered piezoelectric element loses its symmetry. Therefore, the ultrasonic motor using the multilayered piezoelectric element produces a driving velocity difference depending on the driving direction or a positional accuracy difference.

Under the circumstances, the following multilayered piezoelectric element manufacturing method is disclosed in, e.g., Jpn. Pat. Appln. KOKAI Publication No. 11-233846.

That is, the multilayered piezoelectric element manufacturing method disclosed in Jpn. Pat. Appln. KOKAI Publication No. 11-233846 is a multilayered piezoelectric element manufacturing method of forming a primary multilayered structure by alternately stacking a plurality of piezoelectric layers made of a material having an electricity-mechanical energy converting function and a plurality of electrode layers made of an electrode material, and forming a multilayered piezoelectric element by sintering the primary multilayered structure, wherein a mark for detecting a positional shift of each electrode layer in a two-dimensional direction in a plane is formed on the piezoelectric layer.

Accordingly, the technique disclosed in Jpn. Pat. Appln. KOKAI Publication No. 11-233846 provides the multilayered piezoelectric element manufacturing method capable of simply determining the quality of the stacking state of the multilayered piezoelectric element.

### BRIEF SUMMARY OF THE INVENTION

In the technique disclosed in Jpn. Pat. Appln. KOKAI Publication No. 11-233846, however, although a shift is visible in the stacking step, no shift is visible in each individual multilayered piezoelectric element (as a complete product) cut after the stacking step.

Also, in the technique disclosed in Jpn. Pat. Appln. KOKAI Publication No. 11-233846, the mark formed on the piezoelectric layer in order to detect a positional shift of each electrode layer in the two-dimensional direction in a plane is a mark formed for positional shift detection only. Therefore, a space and material for forming this mark are additionally necessary.

Furthermore, to detect positional shifts in the short-side direction, the long-side direction, and a rotational direction in a plane perpendicular to the stacking direction of the piezoelectric layers, two or more positional shift detecting marks must be formed on each piezoelectric layer. Since this further requires spaces and materials for forming the positional shift detecting marks, the manufacturing efficiency decreases.

The present invention has been made in consideration of the above situation, and has as its object to provide a multilayered piezoelectric element by which the stacking accuracy (shifts in the short-side direction, the long-side direction, and a rotational direction in a plane perpendicular to the stacking direction of rectangular piezoelectric materials forming the multilayered piezoelectric element) of the multilayered piezoelectric element can be detected after the multilayered piezoelectric element is completed, and neither a new material nor a new space is necessary to achieve the detection, and provide an ultrasonic motor including the multilayered piezoelectric element.

According to an aspect of a multilayered piezoelectric element of the present invention, there is provided a multilayered piezoelectric element formed by alternately stacking:

a plurality of first piezoelectric materials each comprising first internal electrodes, and having a rectangular sectional shape in a direction parallel to a surface where the first internal electrodes are formed; and

a plurality of second piezoelectric materials each comprising second internal electrodes, and having the same rectangular sectional shape as that of the first piezoelectric material in a direction parallel to a surface where the second internal electrodes are formed,

wherein the first internal electrodes comprise first exposed portions which are extended toward at least two sides, including two non-opposite sides, of four sides forming the sectional shape of the first piezoelectric material, and which are formed at an end portion of the first piezoelectric material,

the second internal electrodes comprise second exposed portions which are extended toward at least two sides, including two non-opposite sides, of four sides forming the sectional shape of the second piezoelectric material, and which are formed at an end portion of the second piezoelectric material, and

a stacking accuracy of the first piezoelectric materials and the second piezoelectric materials is detectable based on the first exposed portions and the second exposed portions.

Furthermore, according to an aspect of an ultrasonic motor comprising a multilayered piezoelectric element formed by alternately stacking:

a plurality of first piezoelectric materials each comprising first internal electrodes, and having a rectangular sectional shape in a direction parallel to a surface where the first internal electrodes are formed; and

a plurality of second piezoelectric materials each comprising second internal electrodes, and having the same rectangular sectional shape as that of the first piezoelectric material in a direction parallel to a surface where the second internal electrodes are formed, the ultrasonic motor being configured to generate elliptical vibration by simultaneously generating a longitudinal vibrational mode and a flexural vibrational mode in the multilayered piezoelectric element, and drive a driven member by obtaining a driving force by the elliptical vibration,

wherein the first internal electrodes comprise first exposed portions which are extended toward at least two sides, including two non-opposite sides, of four sides forming the sectional shape of the first piezoelectric material, and which are formed at an end portion of the first piezoelectric material,

the second internal electrodes comprise second exposed portions which are extended toward at least two sides, including two non-opposite sides, of four sides forming the sectional shape of the second piezoelectric material, and which are formed at an end portion of the second piezoelectric material, and

a stacking accuracy of the first piezoelectric materials and the second piezoelectric materials is detectable based on the first exposed portions and the second exposed portions.

### BRIEF DESCRIPTION OF THE SEVERAL VIEWS OF THE DRAWING

FIG. 1 is a view showing a configuration example of an ultrasonic motor according to an embodiment of the present invention;

FIG. 2A is a view showing a configuration example of a piezoelectric material forming a multilayered piezoelectric element;

FIG. 2B is a view showing a configuration example of a piezoelectric material forming the multilayered piezoelectric element;

FIG. 3A is an exemplary view showing an example of a stack when a plurality of layers of the piezoelectric materials shown in FIGS. 2A and 2B are stacked and sintered;

FIG. 3B is a view showing the external electrode formation surfaces of the multilayered piezoelectric element;

FIG. 4A is a view showing an example of an external electrode formation surface C′ when the stacking accuracy in the short-side direction is high;

FIG. 4B is a view showing an example of the external electrode formation surface C′ when the stacking accuracy in the short-side direction is low;

FIG. 5 is a view showing examples of the connections of power supply members to external electrodes;

FIG. 6 is a view showing the piezoelectric element in which a holding member, driving force extraction member, and power supply member are connected;

FIG. 7 is a view showing the ultrasonic motor according to the embodiment of the present invention as a model by using an equivalent mass m related to the displacement of the piezoelectric element near the driving force extraction member, a force F generated by the vibration of the piezoelectric element near the driving force extraction member, and loads K and C due to the power supply member;

FIG. 8 is a graph in which the vibrational amplitude of the piezoelectric element is represented by the ordinate, and the vibrational frequency of the piezoelectric element is represented by the abscissa;

FIG. 9A is a view showing a configuration example of a piezoelectric material according to the first modification;

FIG. 9B is a view showing a configuration example of a piezoelectric material according to the first modification;

FIG. 10A is a view showing a configuration example of a piezoelectric material according to the second modification;

FIG. 10B is a view showing a configuration example of a piezoelectric material according to the second modification;

FIG. 11A is a view showing a configuration example of a piezoelectric material according to the third modification;

FIG. 11B is a view showing a configuration example of a piezoelectric material according to the third modification;

FIG. 12A is a view showing a configuration example of a piezoelectric material according to the fourth modification;

FIG. 12B is a view showing a configuration example of a piezoelectric material according to the fourth modification;

FIG. 13A is a view showing a configuration example of a piezoelectric material according to the fifth modification;

FIG. 13B is a view showing a configuration example of a piezoelectric material according to the fifth modification;

FIG. 14A is a view showing a configuration example of a piezoelectric material according to the sixth modification;

FIG. 14B is a view showing a configuration example of a piezoelectric material according to the sixth modification;

FIG. 15A is a view showing a configuration example of a piezoelectric material according to the seventh modification;

FIG. 15B is a view showing a configuration example of a piezoelectric material according to the seventh modification;

FIG. 16A is a view showing a configuration example of a piezoelectric material according to the eighth modification; and

FIG. 16B is a view showing a configuration example of a piezoelectric material according to the eighth modification.

### DETAILED DESCRIPTION OF THE INVENTION

A multilayered piezoelectric element and ultrasonic motor according to an embodiment of the present invention will be explained below with reference to the accompanying drawings.

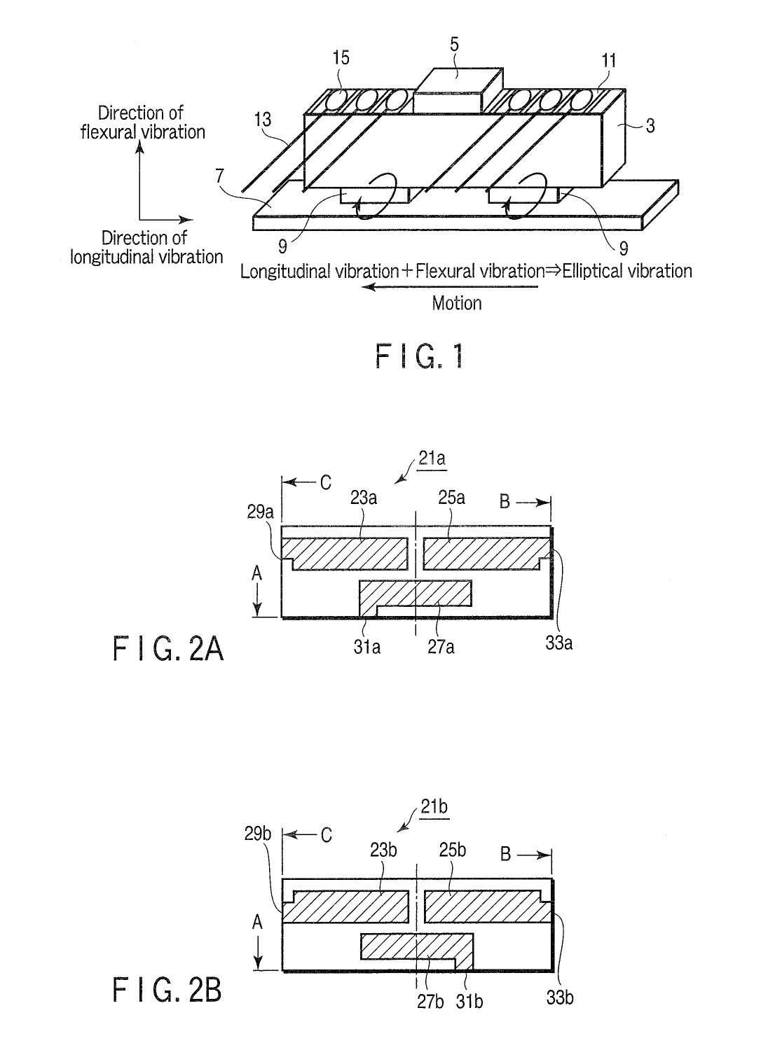

FIG. 1 is a view showing a configuration example of the ultrasonic motor using the multilayered piezoelectric element according to the embodiment of the present invention. As shown in FIG. 1, this ultrasonic motor includes a multilayered piezoelectric element 3, a holding member 5 of the multilayered piezoelectric element 3, a driven member 7, driving force extraction members 9 for driving the driven member 7 by obtaining the driving force from the elliptical vibration (to be described in detail later) of the multilayered piezoelectric element 3, external electrodes 11 of the multilayered piezoelectric element 3, and power supply members 13 such as lead wires for supplying power to the multilayered piezoelectric element 3. Note that the external electrodes 11 and power supply members 13 are soldered by solder junction portions 15.

The multilayered piezoelectric element 3 held by the holding member 5 is in contact with the driven member 7 so as to apply a perpendicular pressing force to the driven member 7 via the driving force extraction members 9.

When two alternating signals having a phase difference are applied to the external electrodes 11 of the multilayered piezoelectric element 3 via the power supply members 13, the multilayered piezoelectric element 3 generates elliptical vibration by synthesizing a longitudinal vibrational mode and a flexural vibrational mode.

The driving force extraction members 9 attached to the multilayered piezoelectric element 3 naturally perform the same elliptical vibration as that of the multilayered piezoelectric element 3. This elliptical motion of the driving force extraction members 9 drives the driven member 7 in contact with the driving force extraction members 9 as described above.

FIGS. 2A and 2B are views showing configuration examples of piezoelectric materials forming the multilayered piezoelectric element 3 described above. In this embodiment, the multilayered piezoelectric element 3 is formed by stacking a plurality of piezoelectric materials 21a shown in FIG. 2A and a plurality of piezoelectric materials 21b shown in FIG. 2B, and sintering the stack.

As shown in FIG. 2A, internal electrodes 23a, 25a, and 27a in three regions formed on the surface of the piezoelectric material 21a each have a portion exposed externally as follows. That is, the internal electrode 23a has an exposed portion 29a extended toward a short side C. The internal electrode 25a has an exposed portion 33a extended toward a short side B. The internal electrode 27a has an exposed portion 31a extended toward a long side A.

Likewise, as shown in FIG. 2B, internal electrodes 23b, 25b, and 27b in three regions formed on the surface of the piezoelectric material 21b each have a portion exposed externally as follows. That is, the internal electrode 23b has an exposed portion 29b extended toward a short side C. The internal electrode 25b has an exposed portion 33b extended toward a short side B. The internal electrode 27b has an exposed portion 31b extended toward a long side A.

The internal electrodes 23a, 25a, and 27a of the piezoelectric material 21a and the internal electrodes 23b, 25b, and 27b of the piezoelectric material 21b are arranged so as to overlap each other when the plurality of piezoelectric materials 21a and the plurality of piezoelectric materials 21b are alternately stacked.

On the other hand, the exposed portions 29a, 31a, and 33a of the piezoelectric material 21a and the exposed portions 29b, 31b, and 33b of the piezoelectric material 21b are arranged so as not to overlap each other (so as not to be superposed on each other) when the plurality of piezoelectric materials 21a and the plurality of piezoelectric materials 21b are alternately stacked.

Note that the material of the piezoelectric materials 21a and 21b is, e.g., lead zirconate titanate. Note also that the thickness of the piezoelectric materials 21a and 21b in the direction perpendicular to the drawing surface is an arbitrary thickness of about 10 to 200 μm.

Furthermore, the material of the internal electrodes 23a, 25a, and 27a and internal electrodes 23b, 25b, and 27b is, e.g., a refractory conductive material such as silver palladium that can withstand the temperature when the piezoelectric materials are sintered.

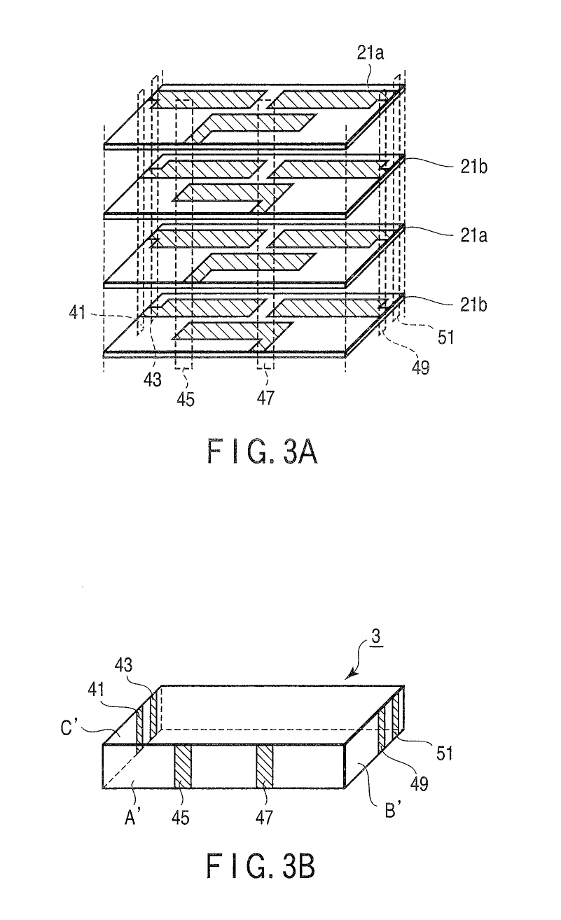

FIGS. 3A and 3B are exemplary views showing an example of a stack when the plurality of piezoelectric materials 21a and the plurality of piezoelectric materials 21b shown in FIGS. 2A and 2B are alternately stacked and sintered. As shown in FIGS. 3A and 3B, after the plurality of piezoelectric materials 21a and the plurality of piezoelectric materials 21b are alternately stacked and sintered, external electrodes are formed by shortcircuiting the above-mentioned exposed portions as follows.

That is, an external electrode 43 is formed by shortcircuiting the exposed portions 29a. An external electrode 41 is formed by shortcircuiting the exposed portions 29b. An external electrode 45 is formed by shortcircuiting the exposed portions 31a. An external electrode 47 is formed by shortcircuiting the exposed portions 31b. An external electrode 51 is formed by shortcircuiting the exposed portions 33a. An external electrode 49 is formed by shortcircuiting the exposed portions 33b.

Note that the material of the external electrodes 41, 43, 45, 47, 49, and 51 is a conductive material such as silver palladium or silver having a thickness of 10 μm or more.

When a polarizing process is performed between, e.g., the external electrodes 41 and 43, only the internal electrodes 23a and 23b as a common region in the stacking direction form a piezoelectric active region. The multilayered piezoelectric element 3 vibrates when an alternating signal is applied between the external electrodes 41 and 43.

Similarly, when the polarizing process is performed between the external electrodes 45 and 47, only the internal electrodes 27a and 27b as a common region in the stacking direction form a piezoelectric active region. The multilayered piezoelectric element 3 vibrates when an alternating signal is applied between the external electrodes 45 and 47. Also, when the polarizing process is performed between the external electrodes 49 and 51, only the internal electrodes 25a and 25b as a common region in the stacking direction form a piezoelectric active region. The multilayered piezoelectric element 3 vibrates when an alternating signal is applied between the external electrodes 49 and 51.

The piezoelectric active region formed by the internal electrodes 23a and 23b and the piezoelectric active region formed by the internal electrodes 25a and 25b are used when simultaneously exciting the longitudinal vibrational mode and flexural vibrational mode in the multilayered piezoelectric element 3, or when exciting only the flexural vibrational mode in the multilayered piezoelectric element 3. On the other hand, the piezoelectric active region formed by the internal electrodes 27a and 27b is used when exciting the longitudinal vibrational mode in the multilayered piezoelectric element 3, or when detecting the vibrational state of the multilayered piezoelectric element 3.

Note that the direction of the above-mentioned polarization is an arbitrary direction. That is, in the same piezoelectric material, the polarization directions in the piezoelectric active region between the internal electrodes 23a and 23b and the piezoelectric active region between the internal electrodes 25a and 25b need not be the same. Note also that the number of piezoelectric materials 21a and 21b to be stacked is an arbitrary number.

If positional variations or blurs occur in the internal electrodes 23a, 25a, 27a, 23b, 25b, and 27b, or if the stacking accuracy of the piezoelectric materials 21a and 21b decreases (if a shift occurs in the long-side direction or short-side direction, or a rotational shift occurs in a plane perpendicular to the stacking direction), the common region (overlapping region) of an internal electrode in which this shift or the like has occurred and an internal electrode facing the former internal electrode reduces, and the ratio accounted for by the piezoelectric active region in the whole piezoelectric material also reduces. This deteriorates the driving characteristics of the multilayered piezoelectric element, or causes a defective electrical connection.

Generally, the decrease in stacking accuracy of the internal electrodes degrades the driving characteristics of the multilayered piezoelectric element or causes a defective electrical connection more often than the dimensional variations or blurs of the internal electrodes. Accordingly, it is desirable to test the stacking accuracy of each individual multilayered piezoelectric element. However, a test using an X-ray transmission image is difficult because the piezoelectric material contains a lead-based substance. Therefore, the above-mentioned shift amount is normally measured by a destructive test using sampling cross-section observation, and each individual multilayered piezoelectric element is not tested.

It is, however, possible to test the stacking accuracy of the multilayered piezoelectric element 3 according to this embodiment as follows by using the exposed portions exposed to an external electrode formation surface A′ formed by the long sides (sides A in FIGS. 2A and 2B) of the piezoelectric materials 21a and 21b shown in FIG. 3B, and exposed to external electrode formation surfaces B′ and C′ formed by the short-sides (sides B and C in FIGS. 2A and 2B).

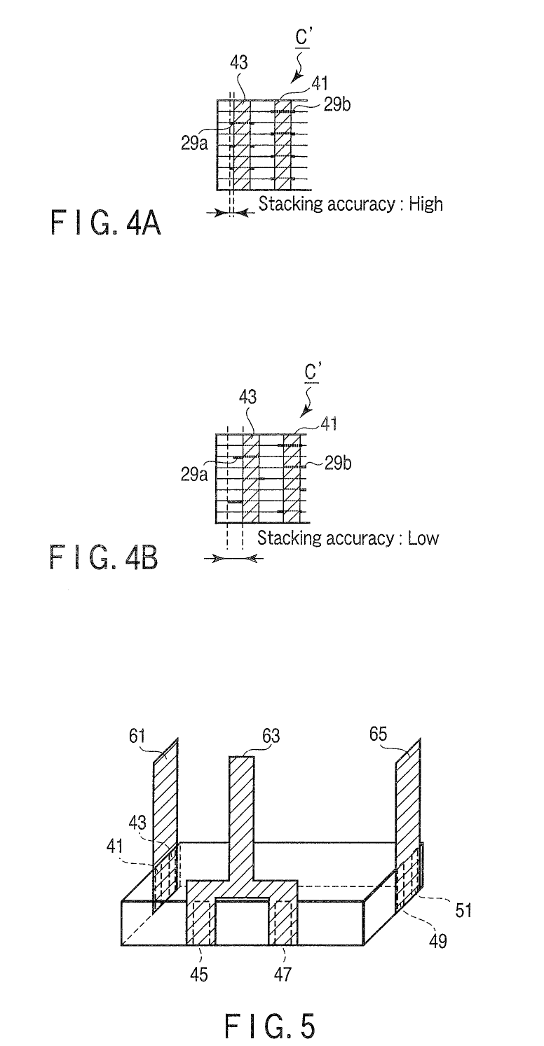

A method of testing the stacking accuracy on the above-mentioned external electrode formation surface C′ will be explained below with reference to FIGS. 4A and 4B. FIG. 4A shows an example of the external electrode formation surface C′ when the stacking accuracy in the short-side direction is high. FIG. 4B shows an example of the external electrode formation surface C′ when the stacking accuracy in the short-side direction is low.

As shown in FIG. 4A, when the stacking accuracy in the short-side direction of the piezoelectric materials 21a and 21b is high, the exposed portions 29a extending from the external electrode 43 are aligned almost straight, and the exposed portions 29b extending from the external electrode 41 are aligned almost straight.

As shown in FIG. 4B, when the stacking accuracy in the short-side direction of the piezoelectric materials 21a and 21b is low, the exposed portions 29a extending from the external electrode 43 are not aligned almost straight but arranged at random, and the exposed portions 29b extending from the external electrode 41 are not aligned almost straight but arranged at random.

The stacking accuracy in the short-side direction of the piezoelectric materials 21a and 21b can also be tested from the arrangement accuracy of the exposed portions 33a and 33b on the external electrode formation surface B′. Likewise, the stacking accuracy in the long-side direction of the piezoelectric materials 21a and 21b can be tested from the arrangement accuracy of the exposed portions 31a and 31b on the external electrode formation surface A′.

The stacking accuracy in the rotational direction in a plane perpendicular to the stacking direction is naturally derived based on the shifts of the exposed portions in the long-side direction and the shifts of the exposed portions in the short-side direction obtained as described above.

Note that when the width of the exposed portions 29a, 29b, 31a, 31b, 33a, and 33b is made larger than that of the external electrodes 41, 43, 45, 47, 49, and 51 as shown in FIGS. 4A and 4B, the arrangement accuracy of the exposed portions 29a, 29b, 31a, 31b, 33a, and 33b extending from the external electrodes 41, 43, 45, 47, 49, and 51 can be observed even after the external electrodes 41, 43, 45, 47, 49, and 51 are formed by printing or the like. The width of the exposed portions 29a, 29b, 31a, 31b, 33a, and 33b is preferably, e.g., 0.2 mm or more.

When the thickness of the external electrodes 41, 43, 45, 47, 49, and 51 is, e.g., about 10 μm, however, the exposed portions 29a, 29b, 31a, 31b, 33a, and 33b can be observed via the external electrodes 41, 43, 45, 47, 49, and 51 even after the external electrodes 41, 43, 45, 47, 49, and 51 are formed by printing or the like, without making the width of the exposed portions 29a, 29b, 31a, 31b, 33a, and 33b larger than that of the external electrodes 41, 43, 45, 47, 49, and 51, as shown in FIGS. 4A and 4B. This makes it possible to detect the arrangement accuracy of the exposed portions 29a, 29b, 31a, 31b, 33a, and 33b.

Note that the visibility of the exposed portions 29a, 29b, 31a, 31b, 33a, and 33b is naturally higher and the above-mentioned stacking accuracy test is of course easier before the step of forming the external electrodes 41, 43, 45, 47, 49, and 51 on the multilayered piezoelectric element 3.

After the stacking accuracy is tested by the method described above, power supply members 63, 65, and 61 such as lead wires or flexible printed circuit boards are connected to the external electrodes 41, 43, 45, 47, 49, and 51 of the multilayered piezoelectric element 3 having stacking accuracy higher than a predetermined stacking accuracy reference. In the example shown in FIG. 5, the power supply member 61 is connected to the external electrodes 41 and 43, the power supply member 63 is connected to the external electrodes 45 and 47, and the power supply member 65 is connected to the external electrodes 49 and 51.

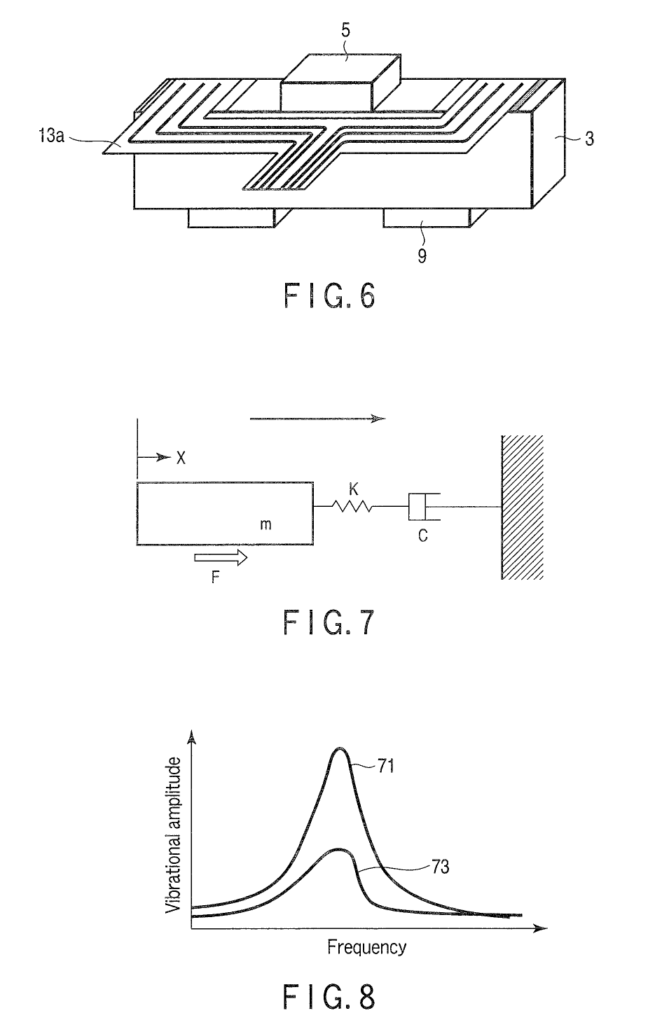

FIG. 6 is a view showing an example of the multilayered piezoelectric element 3 in which the holding member 5, the driving force extraction members 9, and a power supply member 13a are connected.

As shown in FIG. 6, when connecting lines from a plurality of external electrodes are gathered to the power supply member 13a by using, e.g., a flexible printed circuit board, it is possible to reduce the number of parts, and simplify the step of connecting the power supply member 13a. That is, a multilayered piezoelectric element and ultrasonic motor having high productivity can be implemented by simplifying the external electrode printing step and power supply member connecting step. Note that since the flexible printed circuit board is relatively light in weight, the vibrational loss reducing effect is larger than that when lead wires are soldered to external electrodes.

In the multilayered piezoelectric element 3 of the ultrasonic motor explained with reference to FIG. 1, the individual exposed portions are extended and the external electrodes 11 and power supply members 13 are formed so that at least the stacking accuracy in a direction almost parallel to the driving direction of the ultrasonic motor can be detected.

This makes it possible to nondestructively test the symmetry of the multilayered piezoelectric element 3 in the driving direction of the ultrasonic motor as described previously. Accordingly, it is possible to prevent the production of a characteristic difference depending on the moving direction, which is a problem caused by a low stacking accuracy of the piezoelectric materials in the driving direction of the ultrasonic motor.

In this embodiment as has been explained above, it is possible to detect shifts in the short-side direction, the long-side direction, and the rotational direction in a plane perpendicular to the stacking direction of the rectangular piezoelectric materials forming the multilayered piezoelectric element after it is completed. In addition, this embodiment can provide a multilayered piezoelectric element that requires neither a new material nor a new space for achieving the detection, and an ultrasonic motor including the multilayered piezoelectric element.

More specifically, in the multilayered piezoelectric element according to this embodiment, each of the exposed portions formed to extend from the internal electrodes to the outer surfaces is used as a mark for detecting the stacking accuracy as well.

Accordingly, the stacking accuracy of the multilayered piezoelectric element can be nondestructively tested in the long-side direction, the short-side direction, and the rotational direction in a plane perpendicular to the stacking direction described above, for each individual piezoelectric material without any additional material and space for the detection only.

The ultrasonic motor according to this embodiment further achieves the effect of increasing the efficiency by suppressing the vibrational loss caused by the power supply member. This effect will be explained in detail below with reference to FIGS. 1, 7, and 8.

First, the external electrode 11 and power supply member 13 shown in FIG. 1 are essential components for driving the ultrasonic motor. However, the power supply member 13 is also a load that causes the multilayered piezoelectric element 3 to lose its vibration. That is, the power supply member 13 has conventionally been a cause of the decrease in efficiency of an ultrasonic motor.

More specifically, the vibrational loss in the multilayered piezoelectric element 3 is significant when, e.g., the extending direction of the power supply member 13 matches the direction of the longitudinal or flexural vibration of the multilayered piezoelectric element 3.

FIG. 7 is a view showing the ultrasonic motor shown in FIG. 1 as a model by using an equivalent mass m related to displacement near the driving force extraction member 9, a force F generated by vibration near the driving force extraction member 9, and load coefficients K and C indicating the load due to the power supply member 13.

An equation of motion in the vibrational direction near the driving force extraction member 9 is represented by

m\ddot{X}=F−KX−C\dot{X} equation (1)

The load coefficients K and C are coefficients determined by, e.g., the extending direction, type, size, and junction method of the power supply member 13 and the distance to the driving force extraction member 9. A displacement amount X indicates the displacement amount in a main displacement direction near the driving force extraction member 9.

Since the force F generated by the piezoelectric effect of the multilayered piezoelectric element 3 is constant, equation (1) described above can also be expressed by

m\ddot{X}=(const)−(KX−C\dot{X}) equation (2)

The values of K and C in equation (2) can be decreased by making the extending direction of the power supply member 13 independent of a vibrational direction X shown in FIG. 7. That is, it is possible to implement a high-efficiency ultrasonic motor that reduces the vibrational loss due to the power supply member 13 by making the extending direction of the power supply member 13 independent of the vibrational direction X, without changing the design or manufacturing method of the multilayered piezoelectric element 3.

Note that the vibrational direction X in the model explained with reference to FIG. 7 can be regarded as both the vibrational directions of the longitudinal and flexural vibration of the multilayered piezoelectric element 3. That is, the model explained with reference to FIG. 7 is a generalized model applicable to both the longitudinal and flexural vibration of the multilayered piezoelectric element 3.

Accordingly, the vibrational loss due to the power supply member 13 can be minimized by making the extending direction of the power supply member 13 independent of both the longitudinal and flexural vibration of the multilayered piezoelectric element 3. More specifically, the extending direction of the power supply member 13 is preferably set to make an angle of 90° with the vibrational directions of the longitudinal and flexural vibration of the multilayered piezoelectric element 3.

Note that the smaller the vibrational loss due to the power supply member 13, the higher the acceleration of vibration near the driving force extraction member 9, i.e., the higher the efficiency of the ultrasonic motor.

As explained above, the vibrational loss due to the power supply member 13 can be reduced as indicated by the graph shown in FIG. 8 by making the extending direction of the power supply member 13 independent of the directions of the longitudinal and flexural vibration of the multilayered piezoelectric element 3 as shown in FIG. 1. FIG. 8 is a graph in which the vibrational amplitude of the multilayered piezoelectric element 3 is represented by the ordinate, and the vibrational frequency of the multilayered piezoelectric element 3 is represented by the abscissa.

Referring to FIG. 8, a characteristic curve 71 indicates the characteristic of the ultrasonic motor according to this embodiment. On the other hand, a characteristic curve 73 indicates the characteristic of a conventional ultrasonic motor (in which the extending direction of a power supply member matches the direction of the longitudinal or flexural vibration of the multilayered piezoelectric element 3).

That is, when the extending direction of the power supply member 13 is made independent of the directions of the longitudinal and flexural vibration of the multilayered piezoelectric element 3 as in the ultrasonic motor according to this embodiment, it is possible to obtain a high driving efficiency with a small vibrational amplitude loss as indicated by the characteristic curve 71.

The ultrasonic motor according to this embodiment increases the driving efficiency by thus reducing the vibrational loss caused by the power supply member.

Since this embodiment can reduce the vibrational loss due to the power supply member 13 as described above, the power supply member 13 and external electrodes 41, 43, 45, 47, 49, and 51 can be formed in a position corresponding to the antinode of the vibration of the multilayered piezoelectric element 3. This makes it possible to provide an ultrasonic motor having a high degree of freedom of design, in which the formation positions of the power supply member 13 and external electrodes 41, 43, 45, 47, 49, and 51 are not limited.

Although the present invention has been explained above based on the embodiment, the present invention is of course not limited to the above-mentioned embodiment, and various modifications and applications are naturally possible without departing from the spirit and scope of the invention.

As described above, when a shift in the direction of the long side A and a shift in the direction of the short side B or short side C can be detected, it is inevitably possible to detect a shift in the rotational direction in a plane perpendicular to the stacking direction. Based on this, the configurations of the internal electrodes and exposed portions of the piezoelectric materials can also be, e.g., any of the following configurations, instead of the configurations explained with reference to FIG. 2.

### (First Modification)

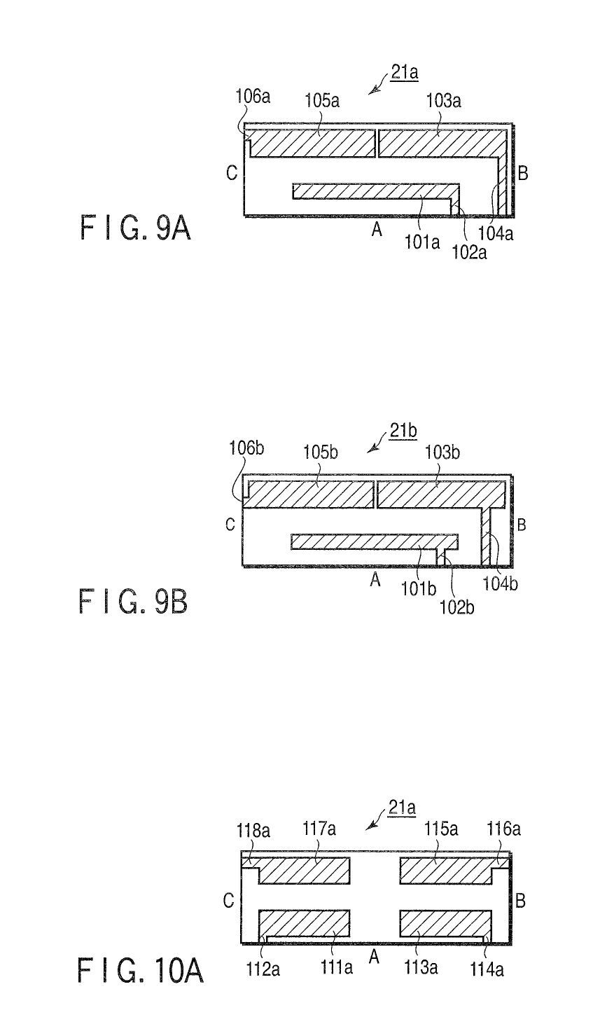

FIG. 9A is a view showing the configuration of a piezoelectric material 21a according to the first modification. FIG. 9B is a view showing the configuration of a piezoelectric material 21b according to the first modification.

As shown in FIG. 9A, the piezoelectric material 21a according to the first modification includes internal electrodes 101a, 103a, and 105a. The internal electrode 101a has an exposed portion 102a extending to a long side A. The internal electrode 103a has an exposed portion 104a extending to the long side A. The internal electrode 105a has an exposed portion 106a extending to a short side C.

As shown in FIG. 9B, the piezoelectric material 21b according to the first modification includes internal electrodes 101b, 103b, and 105b. The internal electrode 101b has an exposed portion 102b extending to a long side A. The internal electrode 103b has an exposed portion 104b extending to the long side A. The internal electrode 105b has an exposed portion 106b extending to a short side C.

The internal electrodes 101a, 103a, and 105a of the piezoelectric material 21a and the internal electrodes 101b, 103b, and 105b of the piezoelectric material 21b are arranged so as to overlap each other when a plurality of piezoelectric materials 21a and a plurality of piezoelectric materials 21b are alternately stacked.

On the other hand, the exposed portions 102a, 104a, and 106a of the piezoelectric material 21a and the exposed portions 102b, 104b, and 106b of the piezoelectric material 21b are arranged so as not to overlap each other (so as not to be superposed on each other) when the plurality of piezoelectric materials 21a and the plurality of piezoelectric materials 21b are alternately stacked.

### (Second Modification)

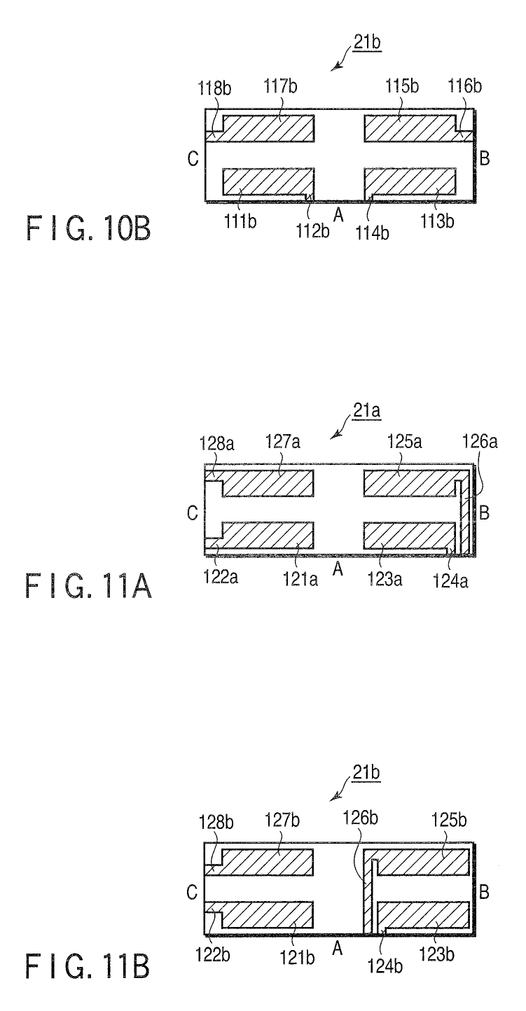

FIG. 10A is a view showing the configuration of a piezoelectric material 21a according to the second modification. FIG. 10B is a view showing the configuration of a piezoelectric material 21b according to the second modification.

As shown in FIG. 10A, the piezoelectric material 21a according to the second modification includes internal electrodes 111a, 113a, 115a, and 117a. The internal electrode 111a has an exposed portion 112a extending to a long side A. The internal electrode 113a has an exposed portion 114a extending to the long side A. The internal electrode 115a has an exposed portion 116a extending to a short side B. The internal electrode 117a has an exposed portion 118a extending to a short side C.

As shown in FIG. 10B, the piezoelectric material 21b according to the second modification includes internal electrodes 111b, 113b, 115b, and 117b. The internal electrode 111b has an exposed portion 112b extending to a long side A. The internal electrode 113b has an exposed portion 114b extending to the long side A. The internal electrode 115b has an exposed portion 116b extending to a short side B. The internal electrode 117b has an exposed portion 118b extending to a short side C.

The internal electrodes 111a, 113a, 115a, and 117a of the piezoelectric material 21a and the internal electrodes 111b, 113b, 115b, and 117b of the piezoelectric material 21b are arranged so as to overlap each other when a plurality of piezoelectric materials 21a and a plurality of piezoelectric materials 21b are alternately stacked.

On the other hand, the exposed portions 112a, 114a, 116a, and 118a of the piezoelectric material 21a and the exposed portions 112b, 114b, 116b, and 118b of the piezoelectric material 21b are arranged so as not to overlap each other (so as not to be superposed on each other) when the plurality of piezoelectric materials 21a and the plurality of piezoelectric materials 21b are alternately stacked.

### (Third Modification)

FIG. 11A is a view showing the configuration of a piezoelectric material 21a according to the third modification. FIG. 11B is a view showing the configuration of a piezoelectric material 21b according to the third modification.

As shown in FIG. 11A, the piezoelectric material 21a according to the third modification includes internal electrodes 121a, 123a, 125a, and 127a. The internal electrode 121a has an exposed portion 122a extending to a short side C. The internal electrode 123a has an exposed portion 124a extending to a long side A. The internal electrode 125a has an exposed portion 126a extending to the long side A. The internal electrode 127a has an exposed portion 128a extending to the short side C.

As shown in FIG. 11B, the piezoelectric material 21b according to the third modification includes internal electrodes 121b, 123b, 125b, and 127b. The internal electrode 121b has an exposed portion 122b extending to a short side C. The internal electrode 123b has an exposed portion 124b extending to a long side A. The internal electrode 125b has an exposed portion 126b extending to the long side A. The internal electrode 127b has an exposed portion 128b extending to the short side C.

The internal electrodes 121a, 123a, 125a, and 127a of the piezoelectric material 21a and the internal electrodes 121b, 123b, 125b, and 127b of the piezoelectric material 21b are arranged so as to overlap each other when a plurality of piezoelectric materials 21a and a plurality of piezoelectric materials 21b are alternately stacked.

On the other hand, the exposed portions 122a, 124a, 126a, and 128a of the piezoelectric material 21a and the exposed portions 122b, 124b, 126b, and 128b of the piezoelectric material 21b are arranged so as not to overlap each other (so as not to be superposed on each other) when the plurality of piezoelectric materials 21a and the plurality of piezoelectric materials 21b are alternately stacked.

### (Fourth Modification)

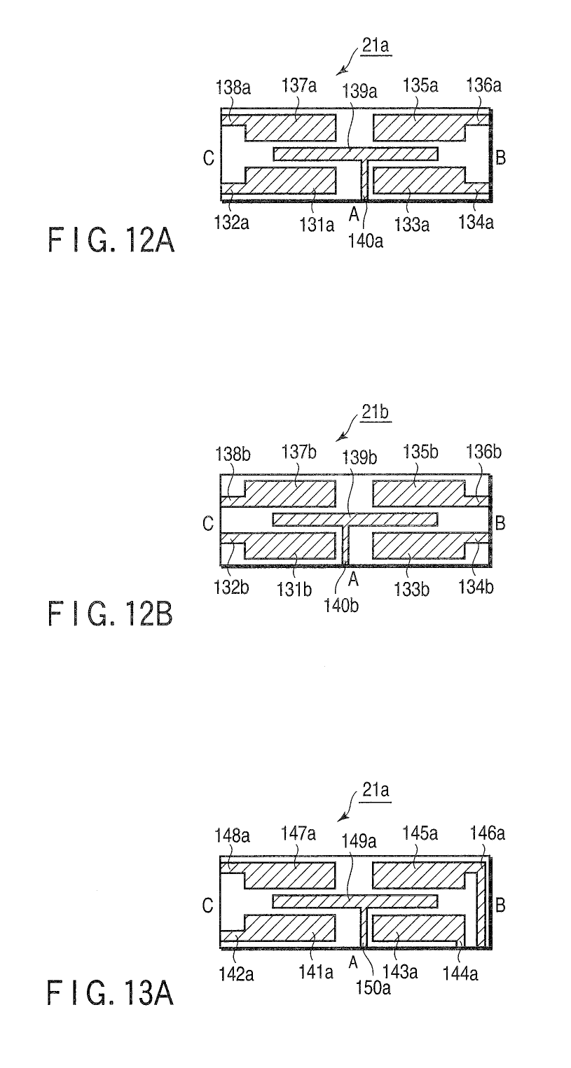

FIG. 12A is a view showing the configuration of a piezoelectric material 21a according to the fourth modification. FIG. 12B is a view showing the configuration of a piezoelectric material 21b according to the fourth modification.

As shown in FIG. 12A, the piezoelectric material 21a according to the fourth modification includes internal electrodes 131a, 133a, 135a, 137a, and 139a. The internal electrode 131a has an exposed portion 132a extending to a short side C. The internal electrode 133a has an exposed portion 134a extending to a short side B. The internal electrode 135a has an exposed portion 136a extending to the short side B. The internal electrode 137a has an exposed portion 138a extending to the short side C. The internal electrode 139a has an exposed portion 140a extending to a long side A.

As shown in FIG. 12B, the piezoelectric material 21b according to the fourth modification includes internal electrodes 131b, 133b, 135b, 137b, and 139b. The internal electrode 131b has an exposed portion 132b extending to a short side C. The internal electrode 133b has an exposed portion 134b extending to a short side B. The internal electrode 135b has an exposed portion 136b extending to the short side B. The internal electrode 137b has an exposed portion 138b extending to the short side C. The internal electrode 139b has an exposed portion 140b extending to a long side A.

The internal electrodes 131a, 133a, 135a, 137a, and 139a of the piezoelectric material 21a and the internal electrodes 131b, 133b, 135b, 137b, and 139b of the piezoelectric material 21b are arranged so as to overlap each other when a plurality of piezoelectric materials 21a and a plurality of piezoelectric materials 21b are alternately stacked.

On the other hand, the exposed portions 132a, 134a, 136a, 138a, and 140a of the piezoelectric material 21a and the exposed portions 132b, 134b, 136b, 138b, and 140b of the piezoelectric material 21b are arranged so as not to overlap each other (so as not to be superposed on each other) when the plurality of piezoelectric materials 21a and the plurality of piezoelectric materials 21b are alternately stacked.

### (Fifth Modification)

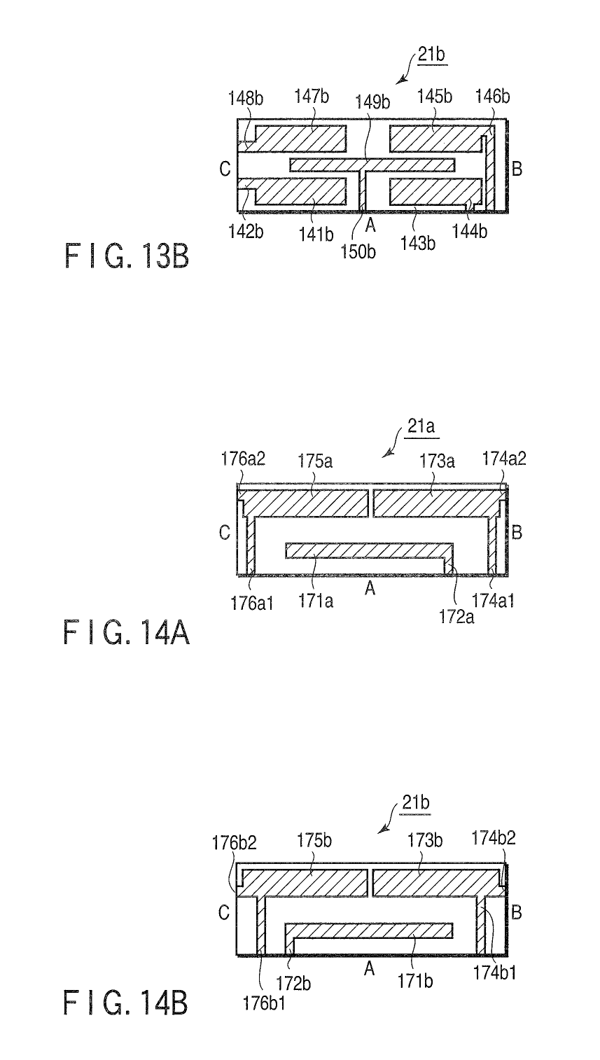

FIG. 13A is a view showing the configuration of a piezoelectric material 21a according to the fifth modification. FIG. 13B is a view showing the configuration of a piezoelectric material 21b according to the fifth modification.

As shown in FIG. 13A, the piezoelectric material 21a according to the fifth modification includes internal electrodes 141a, 143a, 145a, 147a, and 149a. The internal electrode 141a has an exposed portion 142a extending to a short side C. The internal electrode 143a has an exposed portion 144a extending to a long side A. The internal electrode 145a has an exposed portion 146a extending to the long side A. The internal electrode 147a has an exposed portion 148a extending to the short side C. The internal electrode 149a has an exposed portion 150a extending to the long side A.

As shown in FIG. 13B, the piezoelectric material 21b according to the fifth modification includes internal electrodes 141b, 143b, 145b, 147b, and 149b. The internal electrode 141b has an exposed portion 142b extending to a short side C. The internal electrode 143b has an exposed portion 144b extending to a long side A. The internal electrode 145b has an exposed portion 146b extending to the long side A. The internal electrode 147b has an exposed portion 148b extending to the short side C. The internal electrode 149b has an exposed portion 150b extending to the long side A.

The internal electrodes 141a, 143a, 145a, 147a, and 149a of the piezoelectric material 21a and the internal electrodes 141b, 143b, 145b, 147b, and 149b of the piezoelectric material 21b are arranged so as to overlap each other when a plurality of piezoelectric materials 21a and a plurality of piezoelectric materials 21b are alternately stacked.

On the other hand, the exposed portions 142a, 144a, 146a, 148a, and 150a of the piezoelectric material 21a and the exposed portions 142b, 144b, 146b, 148b, and 150b of the piezoelectric material 21b are arranged so as not to overlap each other (so as not to be superposed on each other) when the plurality of piezoelectric materials 21a and the plurality of piezoelectric materials 21b are alternately stacked.

### (Sixth Modification)

FIG. 14A is a view showing the configuration of a piezoelectric material 21a according to the sixth modification. FIG. 14B is a view showing the configuration of a piezoelectric material 21b according to the sixth modification.

As shown in FIG. 14A, the piezoelectric material 21a according to the sixth modification includes internal electrodes 171a, 173a, and 175a. The internal electrode 171a has an exposed portion 172a extending to a long side A. The internal electrode 173a has an exposed portion 174a1 extending to the long side A and an exposed portion 174a2 extending to a short side B. The internal electrode 175a has an exposed portion 176a1 extending to the long side A and an exposed portion 176a2 extending to a short side C.

As shown in FIG. 14B, the piezoelectric material 21b according to the sixth modification includes internal electrodes 171b, 173b, and 175b. The internal electrode 171b has an exposed portion 172b extending to a long side A. The internal electrode 173b has an exposed portion 174b1 extending to the long side A and an exposed portion 174b2 extending to a short side B. The internal electrode 175b has an exposed portion 176b1 extending to the long side A and an exposed portion 176b2 extending to a short side C.

The internal electrodes 171a, 173a, and 175a of the piezoelectric material 21a and the internal electrodes 171b, 173b, and 175b of the piezoelectric material 21b are arranged so as to overlap each other when a plurality of piezoelectric materials 21a and a plurality of piezoelectric materials 21b are alternately stacked.

On the other hand, the exposed portions 172a, 174a1, 174a2, 176a1, and 176a2 of the piezoelectric material 21a and the exposed portions 172b, 174b1, 174b2, 176b1, and 176b2 of the piezoelectric material 21b are arranged so as not to overlap each other (so as not to be superposed on each other) when the plurality of piezoelectric materials 21a and the plurality of piezoelectric materials 21b are alternately stacked.

### (Seventh Modification)

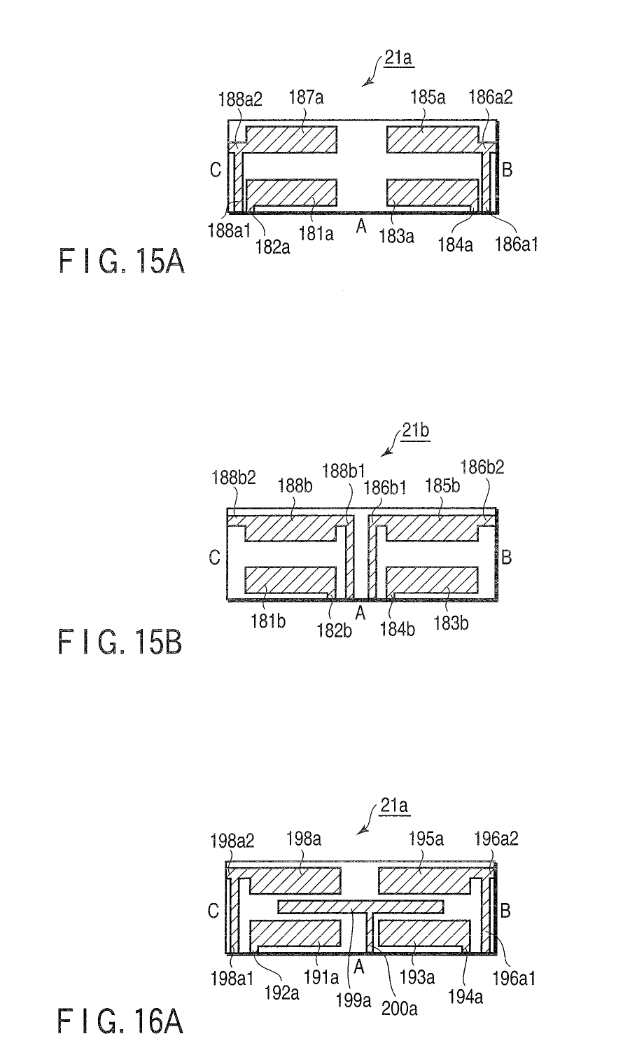

FIG. 15A is a view showing the configuration of a piezoelectric material 21a according to the seventh modification. FIG. 15B is a view showing the configuration of a piezoelectric material 21b according to the seventh modification.

As shown in FIG. 15A, the piezoelectric material 21a according to the seventh modification includes internal electrodes 181a, 183a, 185a, and 187a. The internal electrode 181a has an exposed portion 182a extending to a long side A. The internal electrode 183a has an exposed portion 184a extending to the long side A. The internal electrode 185a has an exposed portion 186a1 extending to the long side A and an exposed portion 186a2 extending to a short side B. The internal electrode 187a has an exposed portion 188a1 extending to the long side A and an exposed portion 188a2 extending to a short side C.

As shown in FIG. 15B, the piezoelectric material 21b according to the seventh modification includes internal electrodes 181b, 183b, 185b, and 187b. The internal electrode 181b has an exposed portion 182b extending to a long side A. The internal electrode 183b has an exposed portion 184b extending to the long side A. The internal electrode 185b has an exposed portion 186b1 extending to the long side A and an exposed portion 186b2 extending to a short side B. The internal electrode 187b has an exposed portion 188b1 extending to the long side A and an exposed portion 188b2 extending to a short side C.

The internal electrodes 181a, 183a, 185a, and 187a of the piezoelectric material 21a and the internal electrodes 181b, 183b, 185b, and 187b of the piezoelectric material 21b are arranged so as to overlap each other when a plurality of piezoelectric materials 21a and a plurality of piezoelectric materials 21b are alternately stacked.

On the other hand, the exposed portions 182a, 184a, 186a1, 186a2, 188a1, and 188a2 of the piezoelectric material 21a and the exposed portions 182b, 184b, 186b1, 186b2, 188b1, and 188b2 of the piezoelectric material 21b are arranged so as not to overlap each other (so as not to be superposed on each other) when the plurality of piezoelectric materials 21a and the plurality of piezoelectric materials 21b are alternately stacked.

### (Eighth Modification)

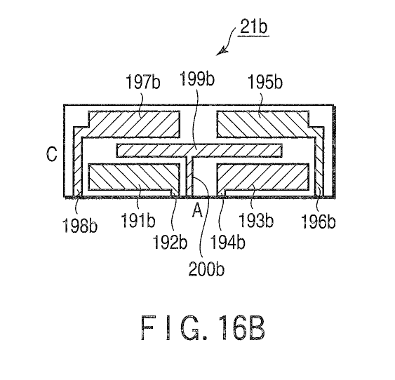

Note that it is of course also possible to configure only the piezoelectric material 21a such that the stacking accuracy in the rotational direction in a plane perpendicular to the stacking direction can be detected. Even when adopting this configuration, it is possible to provide a multilayered piezoelectric element achieving the above-mentioned effects and an ultrasonic motor including the multilayered piezoelectric element. For example, FIG. 16A is a view showing the configuration of a piezoelectric material 21a according to the eighth modification, and FIG. 16B is a view showing the configuration of a piezoelectric material 21b according to the eighth modification.

As shown in FIG. 16A, the piezoelectric material 21a according to the eighth modification includes internal electrodes 191a, 193a, 195a, 197a, and 199a. The internal electrode 191a has an exposed portion 192a extending to a long side A. The internal electrode 193a has an exposed portion 194a extending to the long side A. The internal electrode 195a has an exposed portion 196a1 extending to the long side A and an exposed portion 196a2 extending to a short side B. The internal electrode 197a has an exposed portion 198a1 extending to the long side A and an exposed portion 198a2 extending to a short side C. The internal electrode 199a has an exposed portion 200a extending to the long side A.

As shown in FIG. 16B, the piezoelectric material 21b according to the eighth modification includes internal electrodes 191b, 193b, 195b, 197b, and 199b. The internal electrode 191b has an exposed portion 192b extending to a long side A. The internal electrode 193b has an exposed portion 194b extending to the long side A. The internal electrode 195b has an exposed portion 196b extending to the long side A. The internal electrode 197b has an exposed portion 198b extending to the long side A. The internal electrode 199b has an exposed portion 200b extending to the long side A.

The internal electrodes 191a, 193a, 195a, 197a, and 199a of the piezoelectric material 21a and the internal electrodes 191b, 193b, 195b, 197b, and 199b of the piezoelectric material 21b are arranged so as to overlap each other when a plurality of piezoelectric materials 21a and a plurality of piezoelectric materials 21b are alternately stacked.

On the other hand, the exposed portions 192a, 194a, 196a1, 196a2, 198a1, 198a2, and 200a of the piezoelectric material 21a and the exposed portions 192b, 194b, 196b, 198b, and 200b of the piezoelectric material 21b are arranged so as not to overlap each other (so as not to be superposed on each other) when the plurality of piezoelectric materials 21a and the plurality of piezoelectric materials 21b are alternately stacked.

Furthermore, the above-mentioned embodiments include inventions in various stages, so various inventions can be extracted by appropriately combining a plurality of disclosed constituent elements. For example, even when some of all the constituent elements disclosed in the embodiments are eliminated, an arrangement from which these constituent elements are eliminated can be extracted as an invention, provided that the problems described in the section “Problems to Be Solved by the Invention” can be solved and the effects described in the section “Effects of the Invention” are obtained.

What is claimed is:

1. A multilayered piezoelectric element formed by alternately stacking:
a plurality of first piezoelectric materials each comprising first internal electrodes, and having a rectangular sectional shape in a direction parallel to a surface where the first internal electrodes are formed; and
a plurality of second piezoelectric materials each comprising second internal electrodes, and having the same rectangular sectional shape as that of the first piezoelectric material in a direction parallel to a surface where the second internal electrodes are formed,
wherein the first internal electrodes comprise first exposed portions which are extended toward at least two sides, including two non-opposite sides, of four sides forming the sectional shape of the first piezoelectric material, and which are formed at an end portion of the first piezoelectric material,
the second internal electrodes comprise second exposed portions which are extended toward at least two sides, including two non-opposite sides, of four sides forming the sectional shape of the second piezoelectric material, and which are formed at an end portion of the second piezoelectric material, and
a stacking accuracy of the first piezoelectric materials and the second piezoelectric materials is detectable based on the first exposed portions and the second exposed portions.

2. A multilayered piezoelectric element according to claim 1, further comprising:
first external electrodes electrically connected to the first exposed portions; and
second external electrodes electrically connected to the second exposed portions,
wherein a width and/or thickness of the first external electrodes is set at a value by which the first exposed portions are visible, and
a width and/or thickness of the second external electrodes is set at a value by which the second exposed portions are visible.

3. An ultrasonic motor comprising a multilayered piezoelectric element formed by alternately stacking:
a plurality of first piezoelectric materials each comprising first internal electrodes, and having a rectangular sectional shape in a direction parallel to a surface where the first internal electrodes are formed; and
a plurality of second piezoelectric materials each comprising second internal electrodes, and having the same rectangular sectional shape as that of the first piezoelectric material in a direction parallel to a surface where the second internal electrodes are formed, the ultrasonic motor being configured to generate elliptical vibration by simultaneously generating a longitudinal vibrational mode and a flexural vibrational mode in the multilayered piezoelectric element, and drive a driven member by obtaining a driving force by the elliptical vibration,
wherein the first internal electrodes comprise first exposed portions which are extended toward at least two sides, including two non-opposite sides, of four sides forming the sectional shape of the first piezoelectric material, and which are formed at an end portion of the first piezoelectric material,
the second internal electrodes comprise second exposed portions which are extended toward at least two sides, including two non-opposite sides, of four sides forming the sectional shape of the second piezoelectric material, and which are formed at an end portion of the second piezoelectric material, and
a stacking accuracy of the first piezoelectric materials and the second piezoelectric materials is detectable based on the first exposed portions and the second exposed portions.

4. An ultrasonic motor according to claim 3, further comprising:
first external electrodes electrically connected to the first exposed portions; and
second external electrodes electrically connected to the second exposed portions,
wherein a width and/or thickness of the first external electrodes is set at a value by which the first exposed portions are visible, and
a width and/or thickness of the second external electrodes is set at a value by which the second exposed portions are visible.

5. An ultrasonic motor according to claim 3 or 4, wherein a direction in which the stacking accuracy of the first piezoelectric materials and the second piezoelectric materials is detected includes a direction substantially parallel to the driving direction.
